(19) United States
(12) Patent Application Publication
(10) Pub. No.: US 2016/0056128 A1
(43) Pub. Date: Feb. 25, 2016

(54) CHIP PACKAGE MODULE AND PACKAGE SUBSTRATE

(71) Applicant: Lighten Corporation, Taoyuan City (TW)

(72) Inventor: Shu-Mei KU, Zhongli City (TW)

(21) Appl. No.: 14/832,478

(22) Filed: Aug. 21, 2015

(30) Foreign Application Priority Data
Aug. 21, 2014 (TW) 103128785

(51) Int. Cl. H01L 25/065; H01L 23/367; H01L 23/522; H01L 23/31; H01L 31/02; H01L 33/64; H01L 33/62; H01L 31/0203; H01L 31/024; H01L 23/14; H01L 33/52

(52) U.S. Cl. CPC H01L 25/0657; H01L 23/142; H01L 23/3677; H01L 23/5226; H01L 23/3114; H01L 33/52; H01L 33/647; H01L 33/62; H01L 31/0203; H01L 31/024; H01L 31/02008; H01L 2225/06589; H01L 2225/06541

(57) ABSTRACT

A chip package module and a package substrate are disclosed herein. The package substrate provides a double-sided wiring structure, wherein a circuit layer is electrically connected with at least one chip, and wherein a heat-conduction wiring layer is extended to the underneath layer so as to increase the heat-conduction area and enhance the heat-dissipation efficiency. The present invention can apply to light emitting diode chips or solar chips to overcome the heat-dissipation problem.

### BACKGROUND OF THE INVENTION

1. Field of the Invention

The present invention relates to a chip package technology, particularly to a chip package module and a package substrate, which can effectively dissipate heat.

2. Description of the Prior Art

The light-emitting diode (LED) features long service life, high power efficiency, and durability. Therefore, LED illumination devices become more and more popular under the tendency of environmental protection and green energy. Among various types of light-emitting diodes, the vertical type light-emitting diode is widely used because it has an advantage of high luminous intensity. In the current vertical type LED, there are so many heat-conduction layers under the chip that the thermal resistance of the heat-conduction path is raised. The higher the temperature, the lower the luminous efficiency, and the shorter the service life. Similar problems also occur in the field of solar cells. Temperature increase would decrease the photoelectric conversion efficiency of solar cells. Among various types of solar chips, the concentrator solar chip particularly needs an effective heat-dissipation design.

### SUMMARY OF THE INVENTION

One objective of the present invention is to provide a chip package module and a package substrate, wherein the package substrate has a double-sided wiring structure, and wherein the circuit layer is electrically connected with the chip, and wherein the heat-conduction wiring layer is extended to the lower layer to increase heat-conduction area, whereby the heat-dissipation efficiency is effectively increased.

One embodiment of the present invention proposes a chip package module, which comprises a metallic substrate; a first heat-conduction and electric-insulation layer disposed over the metallic substrate; a heat-conduction wiring layer disposed over the first heat-conduction and electric-insulation layer; a second heat-conduction and electric-insulation layer disposed over the heat-conduction wiring layer; a circuit layer disposed over the second heat-conduction and electric-insulation layer and electrically connected with the heat-conduction wiring layer; at least one chip installed on the circuit layer in a flip-chip way; and an encapsulant covering the chip and a portion of the circuit layer.

Another embodiment of the present invention proposes a package substrate, which comprises a metallic substrate; a first heat-conduction and electric-insulation layer disposed over the metallic substrate; a heat-conduction wiring layer disposed over the first heat-conduction and electric-insulation layer; a second heat-conduction and electric-insulation layer disposed over the heat-conduction wiring layer; and a circuit layer disposed over the second heat-conduction and electric-insulation layer and electrically connected with the heat-conduction wiring layer.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a diagram schematically showing a chip package module according to one embodiment of the present invention;

FIG. 2 is another diagram schematically showing a chip package module according to one embodiment of the present invention;

FIG. 3 is yet another diagram schematically showing a chip package module according to one embodiment of the present invention; and

FIG. 4 is a further diagram schematically showing a chip package module according to one embodiment of the present invention.

### DESCRIPTION OF THE PREFERRED EMBODIMENTS

The technical contents of the present invention will be described in detail with embodiments below. However, these embodiments are only to exemplify the present invention but not to limit the scope of the present invention.

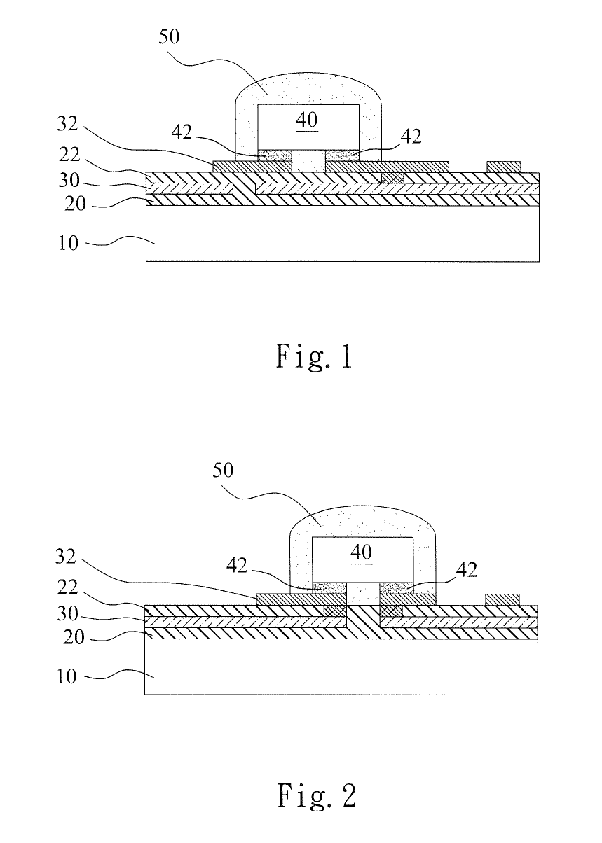

Refer to FIG. 1 a diagram schematically showing a chip package module according to one embodiment of the present invention. The chip package module of the present invention comprises a metallic substrate 10, a first heat-conduction and electric-insulation layer 20, a heat-conduction wiring layer 30, a second heat-conduction and electric-insulation layer 22, a circuit layer 32, at least one chip 40 and an encapsulant 50.

As shown in FIG. 1, the first heat-conduction and electric-insulation layer 20 is disposed over the upper surface of the metallic substrate 10; the heat-conduction wiring layer 30 is disposed over the first heat-conduction and electric-insulation layer 20. The first heat-conduction and electric-insulation layer 20 electrically insulates the heat-conduction wiring layer 30 from the metallic substrate 10. The second heat-conduction and electric-insulation layer 22 is disposed over the heat-conduction wiring layer 30. The circuit layer 32 is disposed over the second heat-conduction and electric-insulation layer 22. The circuit layer 32 is electrically connected with the heat-conduction wiring layer 30. At least one chip 40 is disposed on the circuit layer 32 in a flip-chip way and electrically connected with the circuit layer 32. The encapsulant 50 covers the chip 40 and a portion of the circuit layer 32. The chip 40 is electrically connected with the circuit layer 32 through electric-conduction material 42, such as solder balls or solder bumps.

In the embodiment shown in FIG. 1, the circuit layer 32, the second heat-conduction and electric-insulation layer 22, and the heat-conduction wiring layer 30 jointly form a three-layered structure, wherein the metallic lines are distributed on the upper surface and the lower surface of the second heat-conduction and electric-insulation layer 22 to form a double-sided wiring structure. The circuit layer 32, which is disposed on the second heat-conduction and electric-insulation layer 22, is electrically connected with the chip 40. The heat generated by the chip 40 is conducted from the circuit layer 32 to the heat-conduction wiring layer 30, which is disposed below the second heat-conduction and electric-insulation layer 22, and then is further conducted downwards to the first heat-conduction and electric-insulation layer 20 and the metallic substrate 10.

In one embodiment, the area of the heat-conduction wiring layer 30 is larger than the area of circuit layer 32. The heat-conduction area and heat-conduction efficiency are increased via extending the metallic lines of the circuit layer 32 to the underneath heat-conduction wiring layer 30.

Refer to FIG. 1 and FIG. 2. In one embodiment, the second heat-conduction and electric-insulation layer 22 has at least two openings (not shown in the drawings) whereby the circuit layer 32 and the heat-conduction wiring layer 30 can be joined with each other in the vertical direction and electrically connected with each other. In one embodiment, the encapsulant 50 covers a portion of the second heat-conduction and electric-insulation layer 22.

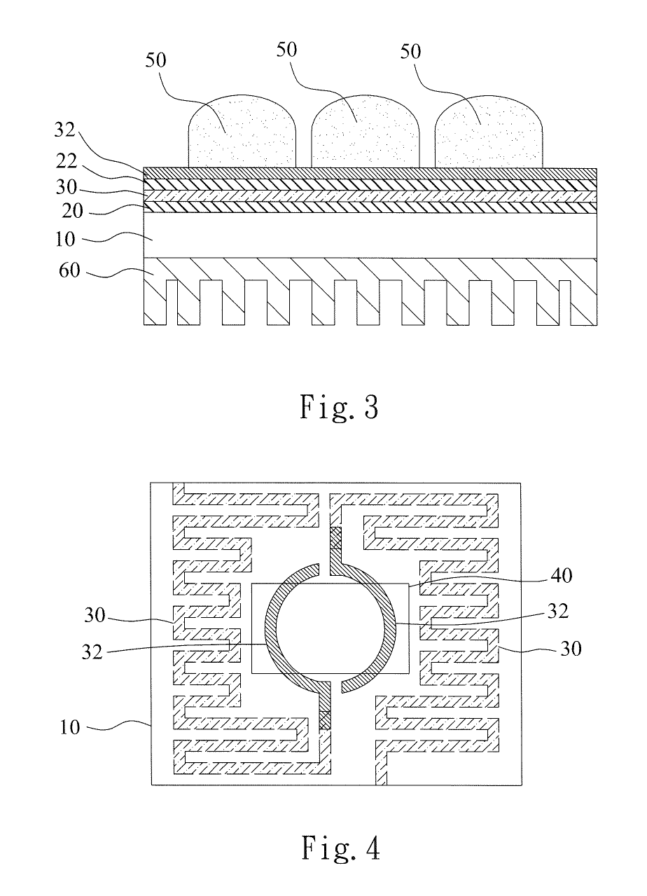

Refer to FIG. 3. In one embodiment, a heat-dissipation element 60 is installed on the lower surface of the metallic substrate 10 to further increase the heat-dissipation efficiency of the chip package module. In the embodiment, the heat generated by the chip 40 is conducted to the metallic substrate 10 and then fast dissipated by the heat-dissipation element 60 on the other side of the metallic substrate 10.

In the chip package module of the present invention, the chip 40 is a light-emitting diode (LED) chip or a solar chip. In one embodiment, the LED chip is a vertical type LED chip, and the P-N electrodes thereof are disposed on the bottom of the chip 40, whereby the chip 40 can be packaged in a flip-chip way. In one embodiment, the solar chip is a high-efficiency concentrator solar chip needing effective heat dissipation, and the double-sided wiring structure of the present invention can fast dissipate heat from the high-efficiency concentrator solar chip.

Refer to FIG. 1 and FIG. 2. The package substrate of the present invention comprises a metallic substrate 10; a first heat-conduction and electric-insulation layer 20 disposed over the metallic substrate 10; a heat-conduction wiring layer 30 disposed over the first heat-conduction and electric-insulation layer 20; a second heat-conduction and electric-insulation layer 22 disposed over the heat-conduction wiring layer 30; and a circuit layer 32 disposed over the second heat-conduction and electric-insulation layer 22, wherein the circuit layer 32 is electrically connected with the heat-conduction wiring layer 30. In one embodiment, the second heat-conduction and electric-insulation layer 22 has at least two openings (not shown in the drawings) allowing vertical electric connection between the circuit layer 32 and the heat-conduction wiring layer 30.

Refer to FIG. 1 and FIG. 2. In the present invention, the configuration of the circuit layer 32, the second heat-conduction and electric-insulation layer 22 and the heat-conduction wiring layer 30 makes the metallic lines distribute on the upper surface and the lower surface of the second heat-conduction and electric-insulation layer 22 to form a double-sided wiring structure. Refer to FIG. 4. The circuit layer 32 is electrically connected with the chip 40. The area of the heat-conduction wiring layer 30 is larger than the area of the circuit layer 32. Via extending the metallic lines of the circuit layer 32 to the underneath heat-conduction wiring layer 30, the present invention effectively enlarges the heat-conduction area, whereby the heat generated by the chip 40 is fast dissipated through the metallic material. Refer to FIG. 3. In one embodiment, a heat-dissipation element 60 is arranged on the lower surface of the metallic substrate 10 of the package substrate.

In conclusion, the package substrate of the present invention uses a double-sided wiring design to enable the heat generated by the chip to be fast dissipated through the path with enlarged heat-conduction area, wherein the circuit layer of the double-sided wiring structure is electrically connected with the chip, and the heat-conduction wiring layer is extended to the lower layer so as to further enlarge the heat-conduction area. Thereby, the present invention can effectively increase the heat-dissipation efficiency of the chip package module and prolong the service life of the chip package module.

Although the present invention has been explained in relation to its preferred embodiment, it is to be understood that other modifications and variation can be made without departing the spirit and scope of the invention as hereafter claimed.

What is claimed is:

1. A chip package module comprising
a metallic substrate;
a first heat-conduction and electric-insulation layer disposed over said metallic substrate;
a heat-conduction wiring layer disposed over said first heat-conduction and electric-insulation layer;
a second heat-conduction and electric-insulation layer disposed over said heat-conduction wiring layer;
a circuit layer disposed over said second heat-conduction and electric-insulation layer and electrically connected with said heat-conduction wiring layer;
at least one chip installed on said circuit layer in a flip-chip way; and
an encapsulant covering said chip and a portion of said circuit layer.

2. The chip package module according to claim 1, wherein said encapsulant further covers a portion of said first heat-conduction and electric-insulation layer.

3. The chip package module according to claim 1 further comprising a heat-dissipation element arranged below said metallic substrate.

4. The chip package module according to claim 1, wherein said second heat-conduction and electric-insulation layer has at least two openings for vertical electric connection of said circuit layer and said heat-conduction wiring layer.

5. The chip package module according to claim 1, wherein said chip is a light-emitting diode chip or a solar chip.

6. The chip package module according to claim 1, wherein area of said heat-conduction wiring layer is larger than area of said circuit layer.

7. The chip package module according to claim l further comprising an electric-conduction material for electrically connecting said chip and said circuit layer.

8. A package substrate comprising
a metallic substrate;
a first heat-conduction and electric-insulation layer disposed over said metallic substrate;
a heat-conduction wiring layer disposed over said first heat-conduction and electric-insulation layer;
a second heat-conduction and electric-insulation layer disposed over said heat-conduction wiring layer; and
a circuit layer disposed over said second heat-conduction and electric-insulation layer and electrically connected with said heat-conduction wiring layer.

9. The package substrate according to claim 8 further comprising a heat-dissipation element arranged below said metallic substrate.

10. The package substrate according to claim 8, wherein said second heat-conduction and electric-insulation layer has at least two openings for vertical electric connection of said circuit layer and said heat-conduction wiring layer.
